(19) United States
(12) Patent Application Publication
(10) Pub. No.: US 2026/0139355 A1
(43) Pub. Date: May 21, 2026

(54) DEPOSITION APPARATUS

(71) Applicant: Samsung Display Co., Ltd., Yongin-si, Gyeonggi-do (KR)

(72) Inventors: JUNGHYUN AHN, Yongin-si, Gyeonggi-do (KR); JAESUK MOON, Yongin-si, Gyeonggi-do (KR); SEUNGJIN LEE, Yongin-si, Gyeonggi-do (KR)

(73) Assignee: Samsung Display Co., Ltd., Yongin-si, Gyeonggi-do (KR)

(21) Appl. No.: 18/940,206

(22) Filed: Nov. 7, 2024

(30) Foreign Application Priority Data
Feb. 16, 2024 (KR) 10-2024-0022392

(51) Int. Cl. C23C 14/04

(52) U.S. Cl. CPC C23C 14/042

(57) ABSTRACT

A deposition apparatus includes a mask frame, masks disposed on the mask frame, extending in a first direction, and arranged in a second direction intersecting the first direction, a first plate disposed on the masks, magnet units disposed on the first plate, arranged in the first direction, and including magnets arranged in the second direction, and a rotational driver disposed on the magnets and rotating the magnets. Each of the magnets includes first and second portions with different polarities, the magnets of a (2n-1)-th magnet unit with respect to the first direction are arranged in the order of the first portion and the second portion in the first direction, wherein ‘n’ is a natural number greater than zero, and the magnets of a 2n-th magnet unit with respect to the first direction are arranged in the order of the second portion and the first portion in the first direction.

### CROSS-REFERENCE TO RELATED APPLICATION(S)

This application claims priority to and benefits of Korean Patent Application No. 10-2024-0022392 under 35 U.S.C. § 119, filed on Feb. 16, 2024, in the Korean Intellectual Property Office, the entire contents of which are incorporated herein by reference.

### BACKGROUND

### 1. Technical Field

Embodiments relate to a deposition apparatus used in a deposition process for manufacturing a display panel.

### 2. Description of Related Art

In recent years, an organic light emitting diode display (OLED) has been spotlighted as a next generation flat display device for excellent brightness and wide viewing angle. Since the organic light emitting diode display does not need a separate light source different from a liquid crystal display, it is manufactured to have a thin thickness and a light weight. For example, the organic light emitting diode display has properties, such as low power consumption, high brightness, fast response speed, etc.

In case that organic light emitting elements are manufactured, a mask is disposed on a substrate, and an organic material used to form an organic light emitting layer is provided on the substrate through openings passing through the mask. Since the mask includes metal and is formed to be very thin, it does not remain flat. A mask frame, which fixes the mask, and magnets, which hold the mask to the substrate to be flat, are used to maintain the mask flat.

However, a repulsive force occurs between the mask and the magnets according to an arrangement manner of the magnets, and the substrate and the mask do not tightly adhered to each other.

### SUMMARY

Embodiments provide a deposition apparatus capable of readily changing a direction in which magnets are aligned according to a direction in which masks extend.

However, embodiments are not limited to those set forth herein. The above and other embodiments will become more apparent to one of ordinary skill in the art to which the disclosure pertains by referencing the detailed description of the disclosure given below.

Embodiments provide a deposition apparatus including a mask frame, masks disposed on the mask frame, extending in a first direction, and arranged in a second direction intersecting the first direction, a first plate disposed on the masks, magnet units disposed on the first plate, arranged in the first direction, and including magnets arranged in the second direction, and a rotational driver disposed on the magnets and rotating the magnets. Each of the magnets may include a first portion and a second portion with a polarity different from a polarity of the first portion. The magnets of a (2n-1)-th magnet unit with respect to the first direction may be arranged in the order of the first portion and the second portion in the first direction, wherein ‘n’ may be a natural number greater than zero. The magnets of a 2n-th magnet unit with respect to the first direction may be arranged in the order of the second portion and the first portion in the first direction.

The first portions of the magnets may be arranged in a first line in the second direction. The second portions of the magnets may be arranged in a second line in the second direction.

Each of the magnets may have a rotation axis substantially parallel to a direction perpendicular to the first direction and the second direction and rotates around the rotation axis.

Each of the magnets has a circular shape in plan view.

Each of the magnets has a polygonal shape in plan view. A circumscribed circle of the polygonal shape of one magnet does not overlap a circumscribed circle of the polygonal shape of other magnets.

The magnets of the 2n-th magnet unit with respect to the first direction may be obtained by shifting the magnets of the (2n-1)-th magnet unit with respect to the first direction to a diagonal direction between the first direction and the second direction.

The magnets in which the first portion faces the first direction may be alternately arranged with the magnets in which the second portion faces the first direction in the diagonal direction.

The deposition apparatus may further driving gears respectively disposed on and combined with the magnets. The rotational driver may be engaged with at least one of the driving gears.

The rotational driver may be engaged with four driving gears.

Each of the magnets may include an insertion space extending from an upper surface of each of the magnets to a lower surface of each of the magnets. Each of the driving gears may include a protrusion portion protruded to a direction perpendicular to the first direction and the second direction and inserted into and fixed to the insertion space.

The driving gears engaged with the rotational driver among the driving gears and the magnets connected to the driving gears may be rotated together by a rotation of the rotational driver.

A direction in which the magnets rotate may be opposite to a direction in which the rotational driver rotates.

The first plate may include an electrostatic chuck or a cooling plate.

The deposition apparatus may further include a second plate disposed on the rotational driver.

The deposition apparatus may further include an elevating driver connected to the second plate on the second plate. The elevating driver moves in a third direction perpendicular to the first direction and the second direction.

Each of the masks may be a fine metal mask and may be magnetic.

Embodiments provide a deposition apparatus including a mask frame, masks disposed on the mask frame, extending in a first direction, and arranged in a second direction intersecting the first direction, a first plate disposed on the masks, and magnetic modules disposed on the first plate. Each of the magnetic modules may include two first magnets arranged spaced apart from each other in the first direction, two second magnets disposed between the first magnets and arranged spaced apart from each other in the second direction, and a rotational driver disposed on the first magnets and the second magnets. The first magnets and the second magnets may be substantially simultaneously rotated by a rotation of the rotational driver.

The first magnets may have a same polarity alignment direction. The second magnets may have a same polarity alignment direction. An N-pole portion of each of the first magnets faces an N-pole portion of one of the second magnets.

An S-pole portion of each of the first magnets may face an S-pole portion of one of the second magnets.

Each of the magnetic modules may further include driving gears disposed on the first magnets and the second magnets, respectively.

According to the deposition apparatus of the disclosure, the magnets may be arranged to allow portions having the same polarity of the magnets to be aligned in the second direction that intersects the first direction of the masks. Accordingly, a repulsive force may not be generated or may be reduced between the magnet units and the masks. Thus, defects in deposition caused by a lifting phenomenon of the mask may be prevented or reduced.

### BRIEF DESCRIPTION OF THE DRAWINGS

The above and other advantages of the disclosure will become readily apparent by reference to the following detailed description when considered in conjunction with the accompanying drawings wherein:

FIG. 1A is a schematic cross-sectional view of a deposition apparatus according to an embodiment;

FIG. 1B is an exploded schematic perspective view of a deposition apparatus according to an embodiment;

FIG. 2 is a schematic cross-sectional view of a deposition apparatus taken along a line I-I′ of FIG. 1B;

FIG. 3 is a schematic cross-sectional view of a deposition apparatus taken along a line I-I′ of FIG. 1B;

FIG. 4 is a schematic perspective view of a magnetic module according to an embodiment;

FIG. 5 is a schematic perspective cross-sectional view of a magnetic module taken along a line II-II′ of FIG. 4;

FIG. 6 is a schematic plan view of an arrangement of magnets according to an embodiment;

FIG. 7 is a schematic plan view of an arrangement of magnets according to an embodiment;

FIG. 8 is an exploded schematic perspective view of a deposition apparatus according to an embodiment;

FIG. 9 is a schematic plan view of a display panel manufactured using a deposition apparatus according to an embodiment;

FIG. 10 is a schematic cross-sectional view of a pixel shown in FIG. 9;

FIG. 11 is a schematic cross-sectional view illustrating a deposition process of a display panel shown in FIG. 10;

FIGS. 12 and 13 are schematic plan views of an arrangement of magnets according to an embodiment; and

FIG. 14 is a schematic plan view of an arrangement of magnets according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described with reference to accompanying drawings.

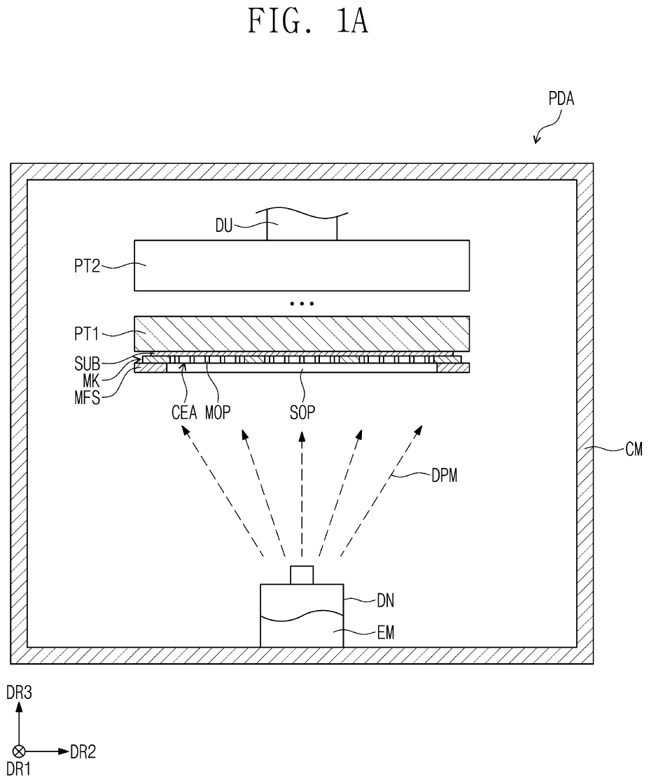

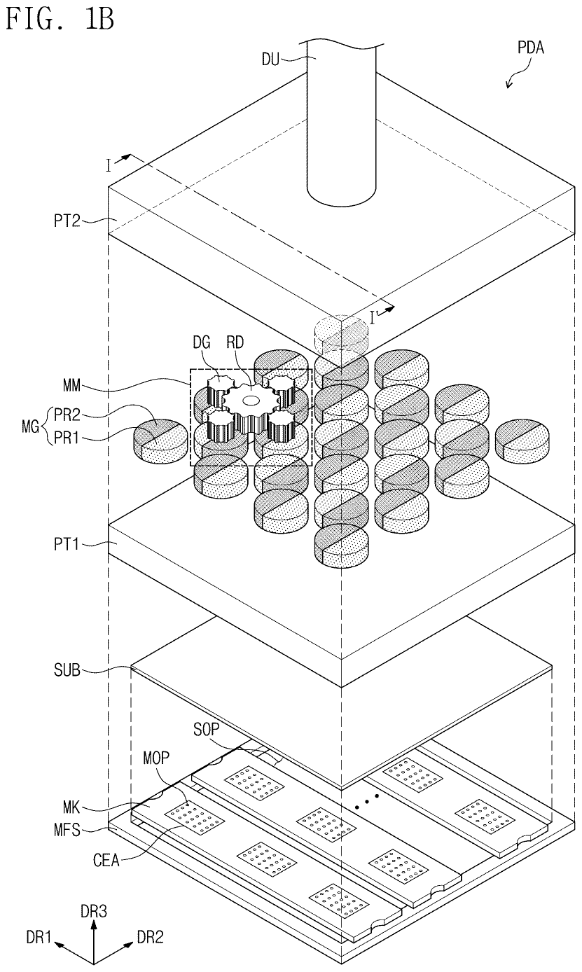

FIG. 1A is a schematic cross-sectional view of a deposition apparatus PDA according to an embodiment, and FIG. 1B is an exploded schematic perspective view of the deposition apparatus PDA according to an embodiment. For the convenience of explanation, a deposition chamber CM and a deposition source DN are omitted in FIG. 1B.

Referring to FIG. 1A, the deposition apparatus PDA may include the deposition chamber CM, the deposition source DN, a mask frame MFS, masks MK, a first plate PT1, a second plate PT2, and an elevating drive unit (or elevating driver) DU. The deposition source DN, the mask frame MFS, the masks MK, the first plate PT1, the second plate PT2, and the elevating drive unit DU may be disposed inside the deposition chamber CM. For example, the deposition apparatus PDA may further include additional mechanical apparatuses to implement an inline system. For descriptive convenience, components disposed between the first plate PT1 and the second plate PT2 are omitted in FIG. 1A, and the omitted components will be described later with reference to FIG. 1B.

The deposition chamber CM may provide an enclosed space to perform a deposition process on a substrate SUB. The deposition chamber CM may set and provide a vacuum state. The deposition chamber CM may include a bottom surface, a ceiling surface, and sidewalls. In an embodiment, the bottom surface of the deposition chamber CM may be substantially parallel to a plane defined by a first direction DR1 and a second direction DR2 intersecting the first direction DR1. A normal line direction of the bottom surface of the deposition chamber CM may be substantially parallel to a third direction DR3. However, the shape of the deposition chamber CM is not limited to that shown in FIG. 1A as long as the deposition chamber CM provides the enclosed space for the deposition process.

The deposition source DN may be disposed in the deposition chamber CM. The deposition source DN may provide a deposition material EM. The deposition material EM may be a sublimable or vaporable material and may include at least one of a metal material, an inorganic material, and an organic material. As an example, the deposition material EM may include a light emitting material.

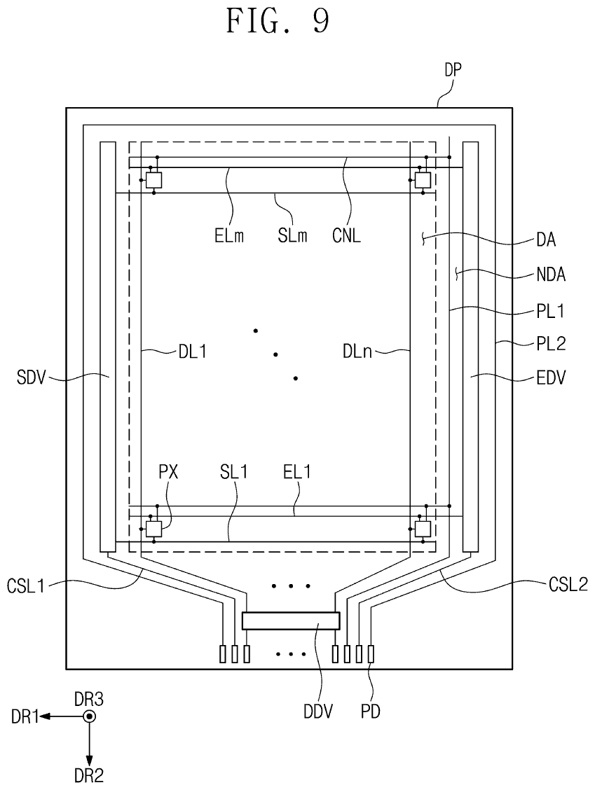

In FIG. 1A, a movement of a gaseous deposition material DPM is shown by a dotted arrow. The gaseous deposition material DPM may be deposited on the substrate SUB in a selected pattern after passing through the mask MK and the mask frame MFS. The substrate SUB may be defined (or formed) as a substrate in an intermediate-stage for manufacturing a display panel DP described with reference to FIG. 9.

Referring to FIGS. 1A and 1B, the mask frame MFS may be a member disposed under the masks MK and supporting the masks MK. The mask frame MFS may have a quadrangular frame shape having edge portions extending in the first direction DR1 and edge portions extending in the second direction DR2. The mask frame MFS may include a metal material. As an example, the mask frame MFS may include invar or stainless steel.

A mask opening SOP may pass through the mask frame MFS. The mask opening SOP may be defined (or formed) as a space surrounded by the edge portions of the mask frame MFS. The masks MK may be disposed on the same plane by the mask frame MFS, and the masks MK may be tightly adhered to the substrate SUB in the deposition process.

The masks MK may be disposed on the mask frame MFS. Two sides (e.g., opposite sides) of the masks MK may be connected to the mask frame MFS. As an example, the masks MK may be connected to the mask frame MFS by a welding method.

The masks MK may extend in a direction and may be arranged in a direction intersecting the direction. In the disclosure, the direction in which the masks MK extend may be referred to as an extension direction, and the direction intersecting the extension direction may be referred to as an intersecting direction. As shown in FIG. 1B, the extension direction of the masks MK corresponds to the first direction DR1, and the intersecting direction corresponds to the second direction DR2.

The masks MK may include a metal material. As an example, each of the masks MK may be a fine metal mask (FMM). Accordingly, the masks MK may be magnetic and may be influenced by a magnetic force of magnets MG.

The masks MK may include a cell area CEA defined in the masks MK. The cell area CEA may overlap the mask opening SOP. The cell area CEA may be an area corresponding to an area where the display panel DP (refer to FIG. 9) is to be formed within the substrate SUB in the deposition process using the deposition apparatus PDA. Light emitting elements of a single display panel DP (refer to FIG. 9) may be formed using a single cell area CEA. Unit areas corresponding to the display panel DP (refer to FIG. 9) may be defined in the substrate SUB. After the light emitting elements are formed in the unit areas, the unit areas may be cut and may be used to manufacture the display panels DP (refer to FIG. 9). As shown in FIG. 1B, three cell areas CEA may be defined in each of the masks MK. However, the number of the cell areas CEA defined in one mask MK is not limited thereto.

Cell openings MOP may be defined (or formed) in the cell area CEA. The masks MK may include an open area and a closed area to allow the gaseous deposition material DPM to be deposited at a specific position of the substrate SUB, and the cell openings MOP may correspond to the opened area of the masks MK. The cell openings MOP may be arranged in the first direction DR1 and the second direction DR2. In plan view, the cell openings MOP may overlap the mask opening SOP.

An area except for the cell openings MOP in the cell areas CEA may be defined (or formed) as the closed area of the mask MK. The gaseous deposition material DPM may pass through the cell openings MOP of the mask MK but may not pass through the area except for the cell openings MOP. Accordingly, the gaseous deposition material DPM may be deposited at positions corresponding to (or overlapping) the cell openings MOP on the substrate SUB using the masks MK in which the shape and the position of the cell openings MOP are adjusted.

The first plate PT1 may be disposed on the mask frame MFS and the masks MK. The first plate PT1 may have a hexahedral shape (or plate shape) having an upper surface and a lower surface, which are defined by the first direction DR1 and the second direction DR2 as shown in FIG. 1B. However, the shape of the first plate PT1 is not limited thereto or thereby as long as the first plate PT1 provides the upper and lower surfaces on which the magnet MG is disposed.

The first plate PT1 may compress the substrate SUB to tightly adhere the substrate SUB to the mask MK. The first plate PT1 may include a material that does not prevent the magnetic force of the magnet MG from being transmitted to the mask MK. As an example, the first plate PT1 may include a non-magnetic material.

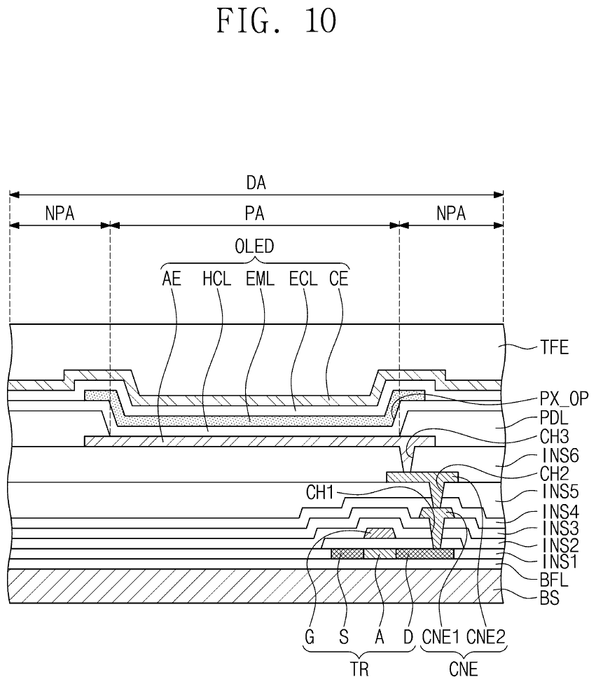

The first plate PT1 may include a cooling plate. A pipe through which a coolant flows may be disposed in the cooling plate. In a case where the substrate SUB is in contact with the first plate PT1 in the deposition process and the substrate SUB is heated by the heated gaseous deposition material DPM (refer to FIG. 10), the substrate SUB may be thermally deformed. However, since the coolant is provided to the first plate PT1 that is in contact with the substrate SUB, the heated substrate SUB may be cooled by the coolant. Accordingly, the thermal deformation of the substrate SUB, which is caused by the heated gaseous deposition material DPM (refer to FIG. 10), may be prevented.

The first plate PT1 may include an electrostatic chuck. The electrostatic chuck may be a member that attaches an object using an electrostatic force. In case that an electric potential is applied to the electrostatic chuck, the object may be charged oppositely and may be fixed to the electrostatic chuck by an attractive force due to the electrostatic force. In case that the first plate PT1 includes the electrostatic chuck, the first plate PT1 may have the electrostatic force. For example, the mask MK may be adhered to the substrate SUB by the attractive electrostatic force of the first plate PT1.

Referring to FIG. 1B, the deposition apparatus PDA may include the magnets MG, a driving gear DG, and a rotational driving unit (or rotational driver) RD, which are disposed between the first plate PT1 and the second plate PT2. For descriptive convenience, in FIG. 1B, the driving gear DG and the rotational driving unit RD, which are disposed on the magnets MG, are omitted in areas other than a dotted rectangular area.

The magnets MG may be disposed on the first plate PT1. The magnets MG may apply the attractive magnetic force to the masks MK to allow the masks MK and the substrate SUB to be tightly adhered to the first plate PT1. For example, the magnets MG may provide the magnetic force in the third direction DR3 to the masks MK that are magnetic, and the masks MK and the substrate SUB may be adhered to the lower surface of the first plate PT1 by the magnetic force.

Referring to FIG. 1B, twenty-five magnets MG are illustrated as an example. One of the twenty-five magnets MG, which is hidden by the second plate PT2, is indicated by a dotted line. However, this is an example to illustrate the arrangement of the magnets MG, and the number of the magnets MG is not limited thereto.

The magnets MG may include a first portion PR1 having a first polarity and a second portion PR2 having a second polarity. The first polarity and the second polarity may be different from each other. As an example, in case that the first polarity is an N pole, the second polarity may be an S pole, and in case that the first polarity is an S pole, the second polarity may be an N pole.

The magnets MG may have a cylindrical shape or a polygonal column shape. Accordingly, each of the magnets MG may have a circular shape or a polygonal shape in plan view. In FIG. 1B, each of the magnets MG having the cylindrical shape is shown as a representative example. However, the shape of the magnets MG is not limited as long as the magnets MG are rotated as described later.

The driving gear DG may be disposed on the magnets MG. The driving gear DG may function to transmit a power, which is received from the rotational driving unit RD, to the magnet MG.

The rotational driving unit RD may be disposed between the driving gears DG. The rotational driving unit RD may be a member that is engaged with the driving gears DG to provide the power for rotating the magnets MG.

The second plate PT2 may be disposed on the first plate PT1. The second plate PT2 may have a hexahedral shape (or a plate shape) having an upper surface and a lower surface, which are defined by the first direction DR1 and the second direction DR2 as shown in FIG. 1B. However, the shape of the second plate PT2 is not limited thereto or thereby and may have a variety of shapes.

The elevating drive unit DU may be disposed on the second plate PT2. The elevating drive unit DU may be connected to the upper surface of the second plate PT2. The elevating drive unit DU may move in a direction substantially parallel to the third direction DR3. The elevating drive unit DU may have a cylindrical shape extending in the third direction DR3. However, embodiments are not limited thereto or thereby. The elevating driver DU may have a variety of shapes.

A conventional (or typical) deposition apparatus includes magnets to adhere masks to a substrate. However, a repulsive force is partially generated between the masks and the magnets due to a magnetic field generated from the magnets. This repulsive force causes a “lifting phenomenon” that disturbs the sufficient adhesion between the masks and the substrate during a deposition process. Due to the lifting phenomenon of the substrate, defects occur in the substrate in the deposition process.

Hereinafter, the deposition apparatus PDA that readily prevents the lifting phenomenon by rotating the magnets MG disposed on the first plate PT1 and aligning the magnets MG will be described.

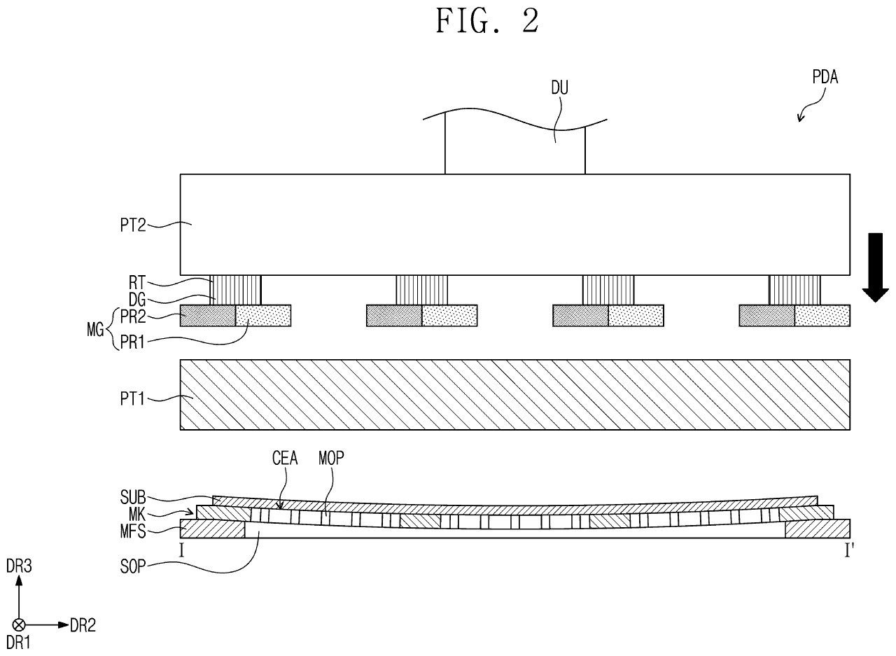

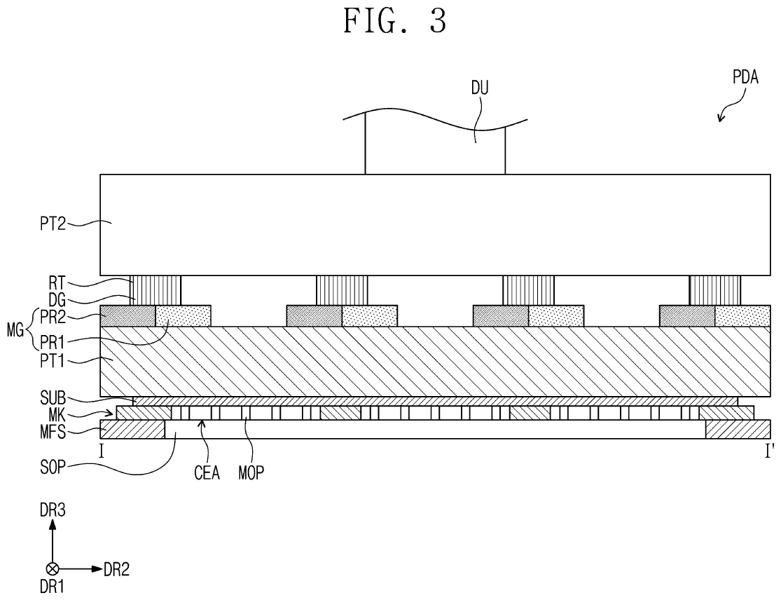

FIGS. 2 and 3 are schematic cross-sectional views of the deposition apparatus taken along a line I-I′ of FIG. 1B. FIG. 3 is a schematic cross-sectional view illustrating a state in which the elevating drive unit DU is descended from a state of FIG. 2.

The driving gear DG may be a rotating member whose central axis is fixed to the lower surface of the second plate PT2. For example, the driving gear DG may rotate in place about the central axis, which is a rotation axis fixed to the lower surface of the second plate PT2.

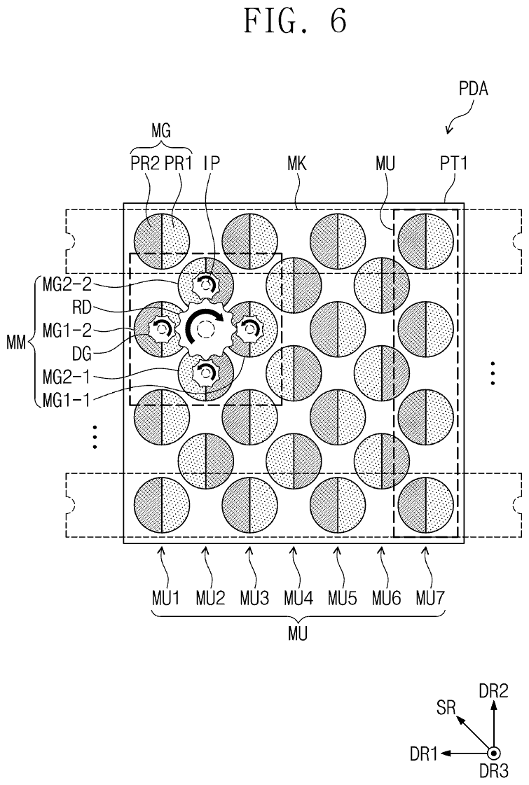

The driving gear DG may be engaged with the rotational driving unit RD (refer to FIG. 6) and may transmit the rotation of the rotational driving unit RD to each of the magnets MG. For example, due to the rotation of the rotational driving unit RD, the driving gears DG engaged with the rotational driving unit RD among the driving gears DG and the magnets MG connected to the driving gears DG may rotate together. The rotation of the driving gear DG will be described in detail with reference to FIG. 6.

Since the mask MK is not subjected to a normal force (or vertical force) caused by the mask frame MFS in a portion that overlaps the mask opening SOP, the mask MK may be bent in the direction of gravity due to gravitational force. As an example, the masks MK may be bent in a direction opposite to the substrate SUB.

Referring to FIG. 3, in case that the elevating drive unit DU descends, the second plate PT2 and the magnets MG disposed under the second plate PT2 may descend or be lowered. Accordingly, the magnets MG may be in contact with the upper surface of the first plate PT1.

In case that the elevating drive unit DU is lowered, the magnets MG and the masks MK may be disposed closer to each other.

Therefore, the magnetic force provided to the masks MK from the magnets MG in the third direction DR3 may increase. This magnetic force may cancel out (or counteract) the gravity applied to the masks MK, and thus, the masks MK may remain flat and may not be bent.

However, even though the masks MK is not bent, the lifting phenomenon in which the masks MK may not be tightly adhered to the substrate SUB may occur. The lifting phenomenon may be caused by a magnetic field generated between the magnets MG arranged on the second plate PT2.

For example, in case that the extension direction of the masks MK and a direction in which polarities of the magnets MG are aligned are parallel to each other, a repulsive force may partially occur between the masks MK and the magnet MG due to the magnetic field generated by the magnet MG. The repulsive force may cause the lifting phenomenon that disrupts the adhesion between the masks MK and the substrate SUB during the deposition process, and due to the lifting phenomenon deposition defects may occur in the substrate SUB.

To prevent the lifting phenomenon in the conventional (or typical) deposition apparatus, the deposition process is stopped while the magnets MG are separated and rearranged to allow the extension direction of the masks MK and the polarity alignment direction of the magnets MG to be perpendicular to each other. However, according to the deposition apparatus PDA, the polarity alignment direction of the magnets MG may be readily adjusted by rotating the magnets MG. Hereinafter, a method to modify the polarity alignment direction of the magnets MG by rotating the magnets MG is described.

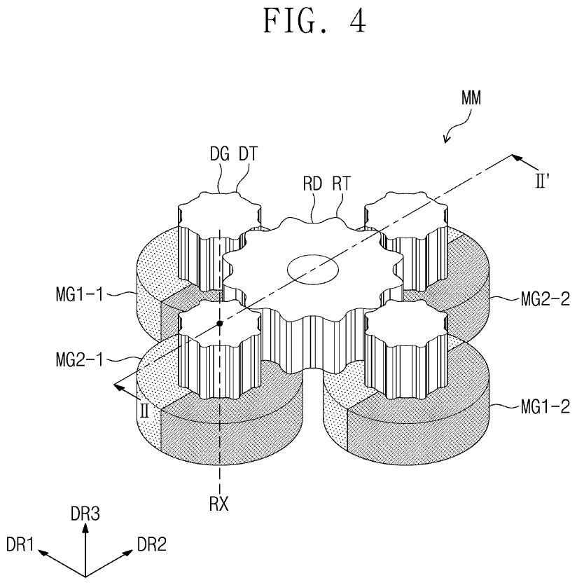

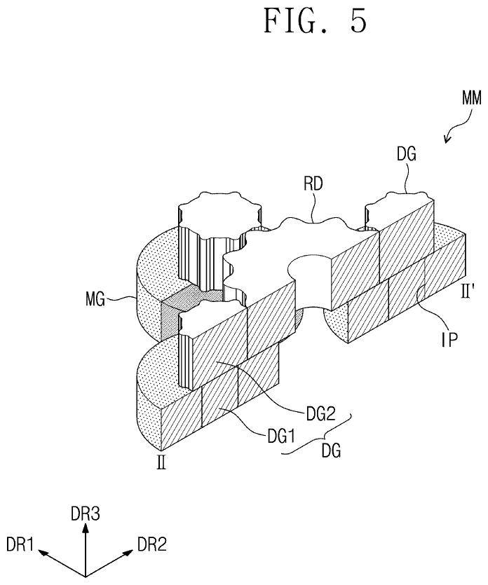

FIG. 4 is a schematic perspective view of a magnetic module MM according to an embodiment, and FIG. 5 is a schematic perspective cross-sectional view of the magnetic module MM taken along a line II-II′ of FIG. 4.

Hereinafter, a structure and a function of the magnetic module MM will be described with reference to FIGS. 4 and 5.

The magnetic module MM may include first magnets MG1-1 and MG1-2 arranged spaced apart from each other in the first direction DR1, second magnets MG2-1 and MG2-2 arranged between the first magnets MG1-1 and MG1-2 and spaced apart from each other in the second direction DR2, the driving gears DG respectively disposed on the first magnets MG1-1 and MG1-2 and the second magnets MG2-1 and MG2-2, and the rotational driving unit RD disposed on the first magnets MG1-1 and MG1-2 and the second magnets MG2-1 and MG2-2 between the driving gears DG.

The magnets MG may have the rotation axis RX that is substantially parallel to the third direction DR3 perpendicular to the first direction DR1 and the second direction DR2.

The rotational driving unit RD may be engaged with the driving gears DG. As an example, the rotational driving unit RD may be engaged with four driving gears among the driving gears DG. Teeth RT of the rotational driving unit RD may be engaged with teeth DT of the driving gears DG.

For example, the rotational driving unit RD may receive a rotational force from a separate power source. As an example, an electric motor placed inside the second plate PT2 (refer to FIG. 3) may receive power to rotate the rotational driving unit RD. However, the type and placement location of the power source that provides the rotational force to the rotational driving unit RD are not limited thereto or thereby.

Since the rotational driving unit RD is engaged with the driving gears DG, the rotational force of the rotational driving unit RD may be transmitted to the driving gears DG.

Referring to FIG. 5, an insertion space IP may be defined (or pass) through the magnets MG and may extend from an upper surface of the magnets MG to a lower surface of the magnets MG.

Each of the driving gears DG may include a first portion DG1 and a second portion DG2 disposed on the first portion DG1. However, the first portion DG1 and the second portion DG2 are separated for descriptive convenience, and each of the driving gears DG may be provided as a single body.

The first portion DG1 may be inserted into the insertion space IP to fix the driving gear DG to the magnet MG. In the following descriptions, the first portion DG1 may be referred to as a protrusion portion.

The protrusion portion DG1 may be inserted into the insertion space IP to combine the driving gears DG to the magnets MG, respectively. However, embodiments are not limited thereto or thereby as long as the magnets MG are combined with the driving gears DG. As an example, the driving gears DG may not include the protrusion portion DG1, and a lower surface of the driving gears DG and the upper surface of the magnets MG may be attached to each other by an adhesive material disposed therebetween.

As described above, the rotational force of the driving gears DG may be transmitted to each of the magnets MG combined with the driving gears DG.

In the embodiment, since the rotational driving unit RD included in the magnetic module MM is engaged with four driving gears DG, four magnets MG may rotate simultaneously in case that a single rotational driving unit RD rotates. Accordingly, the arrangement of the magnets MG may be readily changed.

An N-pole portion of each of the first magnets MG1-1 and MG1-2 may face an N-pole portion of one of the second magnets MG2-1 and MG2-2, and an S-pole portion of each of the first magnets MG1-1 and MG1-2 may face an S-pole portion of one of the second magnets MG2-1 and MG2-2.

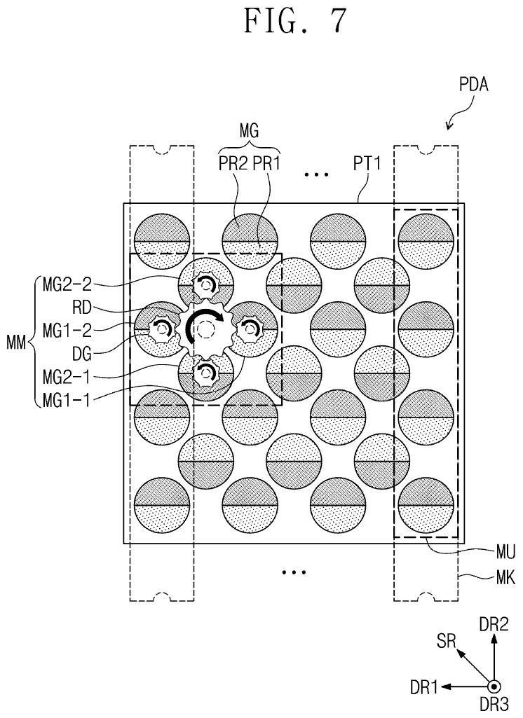

FIG. 6 is a schematic plan view of an arrangement of the magnets MG according to an embodiment. FIG. 7 is a schematic plan view of an arrangement of the magnets MG according to an embodiment. FIG. 7 shows a state in which the rotational driving unit RD is rotated by about 90° in a clockwise direction from a state shown in FIG. 6.

For descriptive convenience, FIGS. 6 and 7 show one rotational driving unit RD and four driving gears DG, which are included in one magnetic module MM, and other rotational driving units and the driving gears are omitted. For example, an outline of the masks MK with the extension direction perpendicular to the polarity alignment direction of the magnets MG is shown by a dotted line.

The deposition apparatus PDA may include magnet units MU disposed on the first plate PT1 and arranged in the first direction DR1, and each of the magnet units MU may include the magnets MG arranged in the second direction DR2.

A 2n-th magnet unit MU with respect to the first direction DR1 may be a magnet unit obtained by shifting a (2n-1)-th magnet unit MU with respect to the first direction DR1 to a diagonal direction SR between the first direction DR1 and the second direction DR2.

Referring to FIG. 6, the magnets MG in which the first portion PR1 faces the first direction DR1 may be alternately arranged with the magnets MG in which the second portion PR2 faces the first direction DR1 along the diagonal direction SR.

The first portion PR1 and the second portion PR2 of the magnets MG included in the (2n-1)-th magnet unit MU with respect to the first direction DR1 may be aligned in the order of the first portion PR1 and the second portion PR2 along the first direction DR1. The first portion PR1 and the second portion PR2 of the magnets MG included in the 2n-th magnet unit MU with respect to the first direction DR1 may be aligned in the order of the second portion PR2 and the first portion PR1 along the first direction DR1.

As shown in FIG. 6, the first portion PR1 and the second portion PR2 included in each of first, third, fifth, and seventh magnet units MU1, MU3, MU5, and MU7 arranged in the first direction DR1 may be aligned in the order of the second portion PR2 and the first portion PR1. Further, the first portion PR1 and the second portion PR2 included in each of second, fourth, and sixth magnet units MU2, MU4, and MU6 arranged in the first direction DR1 may be aligned in the order of the first portion PR1 and the second portion PR2.

A rotation direction of the magnets MG may be opposite to a rotation direction of the rotational driving unit RD. FIG. 6 shows a structure in which the driving gears DG rotate in a counter-clockwise direction in case that the rotational driving unit RD engaged with the driving gears DG rotates in the clockwise direction.

Referring to FIG. 6, the first portions PR1 included in the magnets MG may be aligned in a straight line along the second direction DR2, and the second portions PR2 included in the magnets MG may be aligned in a straight line along the second direction DR2. Accordingly, the magnets MG may have polarity aligned in the second direction DR2. In the disclosure, the expression that the magnets MG have polarity aligned in a direction may mean that portions having the same polarity of the magnets MG are aligned in the direction.

FIG. 7 shows a state in which the magnets MG are rotated by about 90° in the counter-clockwise direction from a state of the magnets MG of FIG. 6.

Referring to FIG. 7, the first portions PR1 included in the magnets MG may be arranged in a straight line along the first direction DR1, and the second portions PR2 included in the magnets MG may be arranged in a straight line along the first direction DR1. Accordingly, the magnets MG may have polarity aligned in the first direction DR1.

In case that the polarity alignment direction of the magnets MG is perpendicular to the extension direction of the mask MK (refer to FIG. 1A), the lifting phenomenon of the mask MK (refer to FIG. 1A) may be reduced or minimized.

Accordingly, in case that the extension direction of the mask MK (refer to FIG. 1A) is the first direction DR1, the magnets MG may have polarity aligned in the second direction DR2, and in case that the extension direction of the mask MK (refer to FIG. 1A) is the second direction DR2, the magnets MG may have polarity aligned in the first direction DR1.

For example, the polarity alignment directions of the first magnets MG1-1 and MG1-2 may be substantially the same as each other, and the polarity alignment directions of the second magnets MG2-1 and MG2-2 may be substantially the same as each other.

Since the deposition apparatus PDA may rotate the rotational driving unit RD and thus may rotate magnets MG, the polarity alignment direction of the magnets MG may be readily changed. Therefore, the lifting phenomenon of the mask MK may be effectively prevented or reduced by considering the extension direction of the mask MK (refer to FIG. 1A).

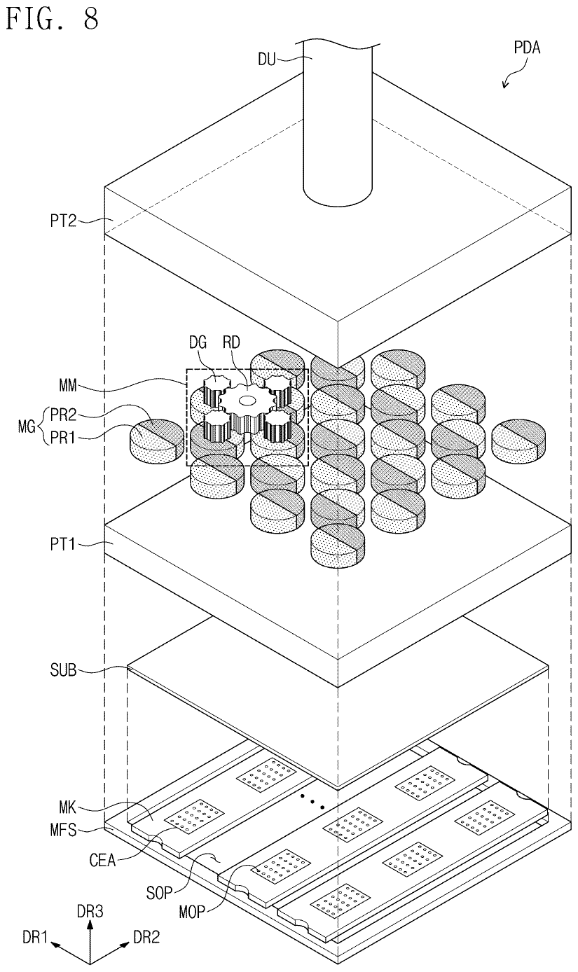

FIG. 8 is an exploded schematic perspective view showing the magnets MG that have polarity aligned in the first direction DR1 in case that the extension direction of the masks MK is the second direction DR2. The alignment of the magnets MG shown in FIG. 8 may be the same as the alignment of the magnets MG of FIG. 7.

Accordingly, even though the magnets MG are arranged on the first plate PT1, the lifting phenomenon of the masks MK may be prevented.

FIG. 9 is a schematic plan view of the display panel DP manufactured using the deposition apparatus according to an embodiment.

Referring to FIG. 9, the display panel DP may have a rectangular shape defined by short sides extending in the first direction DR1 and long sides extending in the second direction DR2. However, the shape of the display panel DP is not limited thereto or thereby. The display panel DP may include a display area DA and a non-display area NDA surrounding the display area DA.

The display panel DP may be a light emitting type display panel. For instance, the display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod. Hereinafter, the organic light emitting display panel will be described as a representative example of the display panel DP.

The display panel DP may include pixels PX, scan lines SL1 to SLm, data lines DL1 to DLn, emission lines EL1 to Elm, first and second control lines CSL1 and CSL2, first and second power lines PL1 and PL2, connection lines CNL, and pads PD. Each of “m” and “n” is a natural number greater than zero.

The pixels PX may be arranged in the display area DA. A scan driver SDV and an emission driver EDV may be disposed in the non-display area NDA respectively adjacent to the long sides of the display panel DP. A data driver DDV may be disposed in the non-display area NDA adjacent to one short side of the short sides of the display panel DP. In plan view, the data driver DDV may be disposed adjacent to a lower end portion of the display panel DP.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The emission lines EL1 to ELm may extend in a direction parallel to the first direction DR1 and may be connected to the pixels PX and the emission driver EDV.

The first power line PL1 may extend in the second direction DR2 and may be disposed in the non-display area NDA. The first power line PL1 may be disposed between the display area DA and the emission driver EDV. However, embodiments are not limited thereto or thereby. According to an embodiment, the first power line PL1 may be disposed between the display area DA and the scan driver SDV.

The connection lines CNL may extend in the first direction DR1 and may be arranged in the second direction DR2. The connection lines CNL may be connected to the first power line PL1 and the pixels PX. A first voltage may be applied to the pixels PX through the first power line PL1 and the connection lines CNL connected to the first power line PL1.

The second power line PL2 may be disposed in the non-display area NDA. The second power line PL2 may extend along the long sides of the display panel DP and the other short side at which the data driver DDV is not disposed in the display panel DP. The second power line PL2 may be disposed outside the scan driver SDV and the emission driver EDV.

For example, the second power line PL2 may extend to the display area DA and may be connected to the pixels PX. A second voltage having a level lower than that of the first voltage may be applied to the pixels PX through the second power line PL2.

The first control line CSL1 may be connected to the scan driver SDV and may extend toward the lower end portion of the display panel DP in plan view. The second control line CSL2 may be connected to the emission driver EDV and may extend toward the lower end portion of the display panel DP in plan view. The data driver DDV may be disposed between the first control line CSL1 and the second control line CSL2.

The pads PD may be disposed on the display panel DP. The pads PD may be disposed closer to the lower end portion of the display panel DP than the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

For example, a timing controller may control an operation of the scan driver SDV, the data driver DDV, and the emission driver EDV and a voltage generator to generate the first and second voltages, and may be disposed on a printed circuit board. The timing controller and the voltage generator may be connected to corresponding pads PD through the printed circuit board.

The scan driver SDV may generate scan signals, and the scan signals may be applied to the pixels PX through the scan lines SL1 to SLm. The data driver DDV may generate data voltages, and the data voltages may be applied to the pixels PX through the data lines DL1 to DLn. The emission driver EDV may generate emission signals, and the emission signals may be applied to the pixels PX through the emission lines EL1 to ELm.

The pixels PX may receive the data voltages in response to the scan signals. The pixels PX may emit a light having a luminance corresponding to the data voltages in response to the emission signals, and thus, an image may be displayed. An emission time of the pixels PX may be controlled by the emission signals.

FIG. 10 is a schematic cross-sectional view of a pixel shown in FIG. 9.

Referring to FIGS. 9 and 10, the pixel PX may be disposed on a base substrate BS and may include a transistor TR and a light emitting element OLED. As an example, one transistor TR is shown in FIG. 10. However, the pixel PX may include transistors and at least one capacitor to drive the light emitting element OLED.

The light emitting element OLED may include a first electrode AE, a second electrode CE, a hole control layer HCL, an electron control layer ECL, and a light emitting layer EML. The first electrode AE may be an anode electrode, and the second electrode CE may be a cathode electrode.

The display area DA may include a light emitting area PA corresponding to the pixel PX and a non-light-emitting area NPA around the light emitting area PA. The light emitting element OLED may be disposed in the light emitting area PA.

The base substrate BS may include a flexible plastic substrate. As an example, the base substrate BS may include transparent polyimide (PI). A buffer layer BFL may be disposed on the base substrate BS, and the buffer layer BFL may be an inorganic layer.

A semiconductor pattern may be disposed on the buffer layer BFL. The semiconductor pattern may include polycrystalline silicon. However, embodiments are not limited thereto or thereby. According to an embodiment, the semiconductor pattern may include amorphous silicon or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially function as a source electrode and a drain electrode of the transistor TR. The low-doped region may substantially correspond to an active region (or a channel) of the transistor TR.

A source region S, an active region A, and a drain region D of the transistor TR may be formed from the semiconductor pattern. A first insulating layer INS1 may be disposed on the semiconductor pattern. A gate G of the transistor TR may be disposed on the first insulating layer INS1. The gate G may overlap the active region A. A second insulating layer INS2 may be disposed on the gate G. A third insulating layer INS3 may be disposed on the second insulating layer INS2.

A connection electrode CNE may be disposed between the transistor TR and the light emitting element OLED to connect the transistor TR to the light emitting element OLED. The connection electrode CNE may include a first connection electrode CNE1 and a second connection electrode CNE2.

The first connection electrode CNE1 may be disposed on the third insulating layer INS3 and may be connected to the drain region D via a first contact hole CH1 defined (or formed) through the first, second, and third insulating layers INS1, INS2, and INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 via a second contact hole CH2 defined (or formed) through the fourth insulating layer INS4 and the fifth insulating layer INS5. A sixth insulating layer INS6 may be disposed on the second connection electrode CNE2. Each of the first to sixth insulating layers INS1 to INS6 may be an inorganic layer or an organic layer.

The first electrode AE may be disposed on the sixth insulating layer INS6. The first electrode AE may be connected to the second connection electrode CNE2 via a third contact hole CH3 defined (or formed) through the sixth insulating layer INS6. A pixel definition layer PDL may be disposed on the first electrode AE and the sixth insulating layer INS6 to expose a selected portion of the first electrode AE. The pixel definition layer PDL may include an opening PX_OP defined (or formed) therethrough to expose the portion of the first electrode AE.

The hole control layer HCL may be disposed on the first electrode AE and the pixel definition layer PDL. The hole control layer HCL may be commonly disposed in the light emitting area PA and the non-light-emitting area NPA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may be commonly disposed in the light emitting area PA and the non-light-emitting area NPA. The electron control layer ECL may include an electron transport layer and an electron injection layer.

The second electrode CE may be disposed on the electron control layer ECL. The second electrode CE may be commonly disposed over the pixels PX. Layers from the buffer layer BFL to the light emitting element OLED may be referred to as a pixel layer.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and an organic layer disposed between the inorganic layers. The inorganic layers may protect the pixel PX from moisture and oxygen. The organic layer may protect the pixel PX from a foreign substance such as dust particles.

The first voltage may be applied to the first electrode AE via the transistor TR, and the second voltage having the level lower than the first voltage may be applied to the second electrode CE. Holes and electrons, which are injected into the light emitting layer EML, may be recombined to generate excitons, and the light emitting element OLED may emit the light by the excitons that return to a ground state from an excited state.

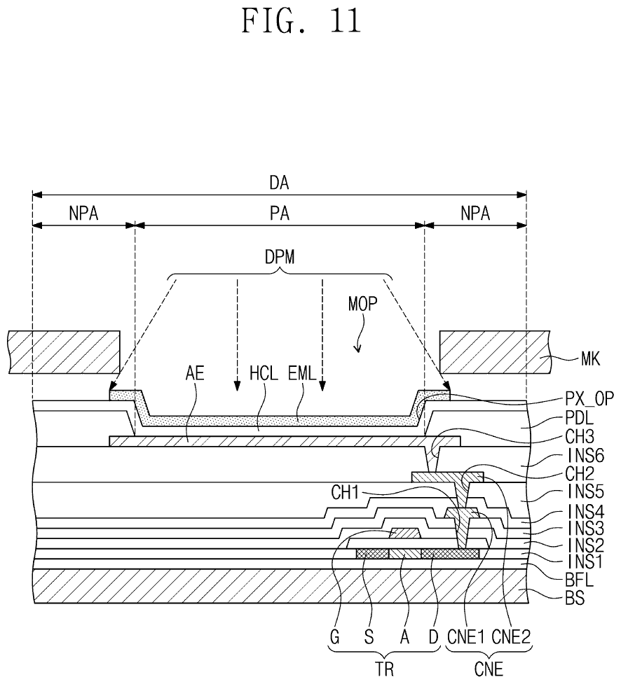

FIG. 11 is a schematic cross-sectional view illustrating the deposition process of the display panel shown in FIG. 10.

The layers, which are stacked from the base substrate BS to the first electrode AE, may correspond to the substrate SUB of FIG. 1A. However, embodiments are not limited thereto or thereby. According to an embodiment, components of the substrate SUB (refer to FIG. 1A) may vary according to an object to be formed by the deposition process.

The masks MK may be disposed to face the substrate SUB (refer to FIG. 1A) to form the light emitting layer EML through the deposition process. The masks MK may be disposed adjacent to the substrate SUB (refer to FIG. 1A).

The gaseous deposition material DPM may be provided on the substrate SUB (refer to FIG. 1A) via the cell opening MOP defined (or formed) through the masks MK. The light emitting layer EML may be formed on the substrate SUB (refer to FIG. 1A) using the gaseous deposition material DPM.

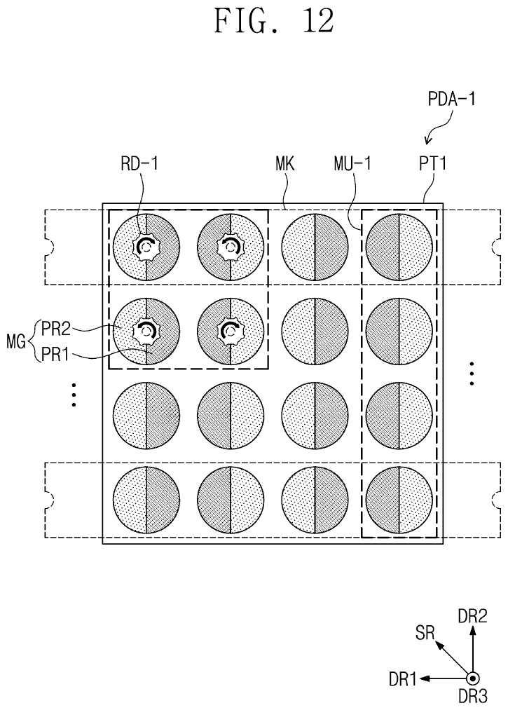

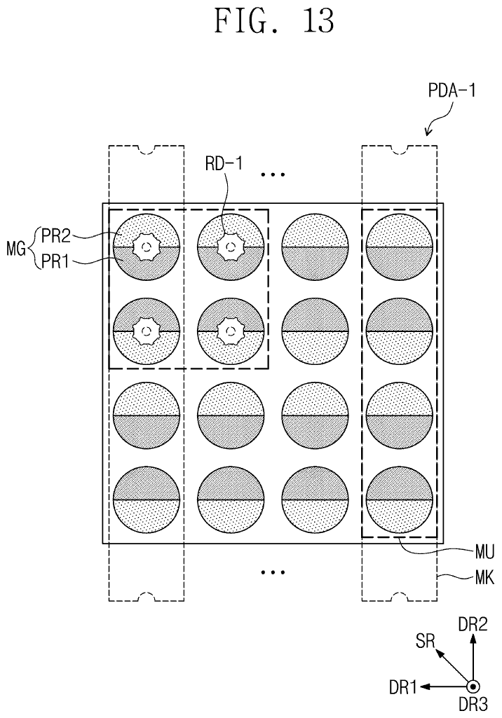

FIG. 12 is a schematic plan view of an arrangement of magnets MG according to an embodiment. FIG. 13 is a schematic plan view of an arrangement of magnets MG according to an embodiment. FIG. 13 is a schematic view showing a state obtained by rotating the magnets MG of FIG. 12 to change the polarity alignment direction. In FIGS. 12 and 13, the same/similar reference numerals denote the same/similar elements in FIGS. 1A to 11, and thus, detailed descriptions of the same/similar elements will be omitted for descriptive convenience.

For descriptive convenience, in FIGS. 12 and 13, an outline of masks MK with an extension direction perpendicular to the polarity alignment direction of the magnets MG is shown by a dotted line.

Referring to FIG. 12, the magnets MG may be arranged spaced apart from each other in the first direction DR1 and the second direction DR2.

Rotational driving units RD-1 may be disposed on the magnets MG, respectively. For example, the rotational driving units RD-1 according to an embodiment may be disposed on the magnets MG, respectively, and may rotate (e.g., directly rotate) the magnets MG, respectively. In an embodiment, a deposition apparatus PDA-1 may not include the driving gear DG (refer to FIG. 1A), and the rotational driving units RD-1 may transmit (e.g., directly transmit) a rotational force to the magnets MG.

Referring to FIG. 12, the magnets MG may have polarity aligned in the second direction DR2. Accordingly, the lifting phenomenon of the masks MK (refer to FIG. 1A) having a shape extending in the first direction DR1 may be prevented.

Each of the rotational driving units RD-1 may rotate the magnets MG and may allow the magnets MG adjacent to each other in the second direction DR2 to face the same poles of each other. As an example, in a dotted rectangular area, the magnets MG positioned at a left upper end and a right lower end may be rotated by about 90° in the clockwise direction, and the magnets MG positioned at a right upper end and a left lower end may be rotated by about 90° in the counter-clockwise direction.

The magnets MG shown in FIG. 13 may have polarity aligned in the first direction DR1. Therefore, even though a mask MK having a shape extending in the second direction DR2 is used in a deposition process, the lifting phenomenon of the mask MK (refer to FIG. 1A) may be prevented.

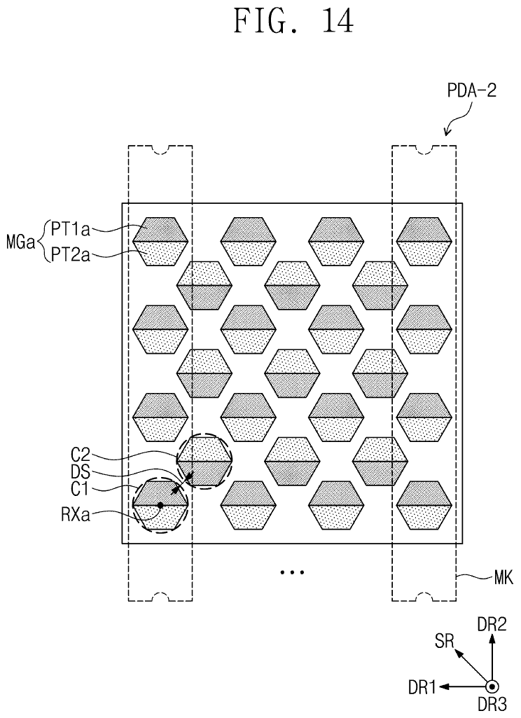

FIG. 14 is a schematic plan view of an arrangement of magnets MGa according to an embodiment. In FIG. 14, the same/similar reference numerals denote the same/similar elements in FIGS. 1A to 11, and thus, detailed descriptions of the same/similar elements will be omitted for descriptive convenience.

For descriptive convenience, in FIG. 14, an outline of masks MK with an extension direction perpendicular to a polarity alignment direction of the magnets MGa is shown by a dotted line.

In an embodiment, each of the magnets MGa may have a polygonal shape in plan view. FIG. 14 shows the magnets MGa each having a hexagonal shape in plan view. However, the shape of the magnets MGa is not limited thereto or thereby.

The magnets MGa may be arranged spaced apart from each other. In case that the magnets MGa rotate around a rotation axis RXa, the magnets MGa may not hinder each other. For the descriptive convenience, FIG. 14 shows two rotating circles C1 and C2 defined along a rotating trajectory of the magnets MGa as a representative example. The rotating circles C1 and C2 may not overlap each other.

Since the magnets MGa are not in contact with each other in case of rotating, the rotating circles C1 and C2 may be spaced apart from each other by a distance DS.

The rotating circles C1 and C2 may correspond to a circumscribed circle of the polygonal shape of the magnets MGa. For example, the circumscribed circles defined by the magnets MGa may not overlap each other.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition apparatus comprising:
a mask frame;
masks disposed on the mask frame, extending in a first direction, and arranged in a second direction intersecting the first direction;
a first plate disposed on the masks;
magnet units disposed on the first plate, arranged in the first direction, and comprising magnets arranged in the second direction; and
a rotational driver disposed on the magnets and rotating the magnets, wherein each of the magnets comprises a first portion and a second portion having a polarity different from a polarity of the first portion,
the magnets of a (2n-1)-th magnet unit with respect to the first direction are arranged in a first order of the first portion and the second portion in the first direction, wherein ‘n’ is a natural number greater than zero, and
the magnets of a 2n-th magnet unit with respect to the first direction are arranged in a second order of the second portion and the first portion in the first direction.

2. The deposition apparatus of claim 1, wherein
the first portions of the magnets are arranged in a first line in the second direction, and
the second portions of the magnets are arranged in a second line in the second direction.

3. The deposition apparatus of claim 1, wherein each of the magnets has a rotation axis substantially parallel to a direction perpendicular to the first direction and the second direction and rotates around the rotation axis.

4. The deposition apparatus of claim 1, wherein each of the magnets has a circular shape in plan view.

5. The deposition apparatus of claim 1, wherein
each of the magnets has a polygonal shape in plan view, and
a circumscribed circle of the polygonal shape of a magnet does not overlap a circumscribed circle of the polygonal shape of another magnets.

6. The deposition apparatus of claim 1, wherein
the magnets of the 2n-th magnet unit with respect to the first direction are obtained by shifting the magnets of the (2n-1)-th magnet unit with respect to the first direction to a diagonal direction between the first direction and the second direction.

7. The deposition apparatus of claim 6, wherein the magnets in which the first portion faces the first direction are alternately arranged with the magnets in which the second portion faces the first direction in the diagonal direction.

8. The deposition apparatus of claim 1, further comprising:
driving gears respectively disposed on the magnets and combined with the magnets,
wherein the rotational driver is engaged with at least one of the driving gears.

9. The deposition apparatus of claim 8, wherein the rotational driver is engaged with four driving gears.

10. The deposition apparatus of claim 1, wherein
each of the magnets includes an insertion space extending from an upper surface of each of the magnets to a lower surface of each of the magnets, and
each of the driving gears comprises a protrusion portion protruded to a direction perpendicular to the first direction and the second direction and inserted into and fixed to the insertion space.

11. The deposition apparatus of claim 1, wherein the driving gears engaged with the rotational driver among the driving gears and the magnets connected to the driving gears are rotated together by a rotation of the rotational driver.

12. The deposition apparatus of claim 11, wherein a direction in which the magnets rotate is opposite to a direction in which the rotational driver rotates.

13. The deposition apparatus of claim 1, wherein the first plate comprises an electrostatic chuck or a cooling plate.

14. The deposition apparatus of claim 1, further comprising:
a second plate disposed on the rotational driver.

15. The deposition apparatus of claim 14, further comprising:
an elevating driver connected to the second plate on the second plate,
wherein the elevating driver moves in a third direction perpendicular to the first direction and the second direction.

16. The deposition apparatus of claim 1, wherein each of the masks is a fine metal mask and is magnetic.

17. A deposition apparatus comprising:
a mask frame;
masks disposed on the mask frame, extending in a first direction, and arranged in a second direction intersecting the first direction;
a first plate disposed on the masks; and
magnetic modules disposed on the first plate, each of the magnetic modules comprising:
two first magnets arranged spaced apart from each other in the first direction;
two second magnets disposed between the first magnets and arranged spaced apart from each other in the second direction; and
a rotational driver disposed on the first magnets and the second magnets,
wherein the first magnets and the second magnets are substantially simultaneously rotated by a rotation of the rotational driver.

18. The deposition apparatus of claim 17, wherein
the first magnets have a same polarity alignment direction, and
the second magnets have a same polarity alignment direction.

19. The deposition apparatus of claim 17, wherein
an N-pole portion of each of the first magnets faces an N-pole portion of one of the second magnets, and
an S-pole portion of each of the first magnets faces an S-pole portion of one of the second magnets.

20. The deposition apparatus of claim 17, wherein each of the magnetic modules further comprises driving gears disposed on the first magnets and the second magnets, respectively.
